(19) United States
(12) Patent Application Publication
(10) Pub. No.: US 2026/0223711 A1
(43) Pub. Date: Jul. 30, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Keigo SATO, Nagano (JP)

(21) Appl. No.: 19/451,731

(22) Filed: Jan. 16, 2026

(30) Foreign Application Priority Data
Jan. 27, 2025 (JP) 2025-011108
Jul. 14, 2025 (JP) 2025-118044

(51) Int. Cl. H10W 70/692; H10W 42/00

(52) U.S. Cl. CPC H10W 70/692; H10W 42/121

(57) ABSTRACT

An interconnect substrate includes a core layer made of glass having one surface and another surface, a first laminate including one or more interconnect layers and one or more insulating layers and disposed on the one surface of the core layer, and a resin portion, wherein a first peripheral portion of the one surface of the core layer is not covered with the first laminate, and wherein the resin portion covers a side surface of the core layer, the first peripheral portion, and a side surface of the first laminate.

### CROSS-REFERENCE TO RELATED APPLICATIONS

The present application is based on and claims priority to Japanese Patent Application Nos. 2025-011108 filed on January 27, 2025, and 2025-118044 filed on July 14, 2025, with the Japanese Patent Office. The entire contents of these applications are incorporated herein by reference.

### FIELD

The disclosures herein generally relate to interconnect substrates and methods of making an interconnect substrate.

### BACKGROUND

As known in the art, interconnect substrates may have core layers and laminates including interconnect layers and insulating layers laminated on the core layers (Patent Document 1). The manufacturing process of an interconnect substrate of such a kind may include, for example, preparing a core layer having a plurality of interconnect regions for singulation into interconnect substrates and cutting regions along which cuts are to be made for singulation, and forming a laminate on the upper surface of the core layer. Thereafter, for example, separation grooves are formed in the laminate at the positions of the cutting regions, and the core layer is cut at the center of the bottom width of each separation groove to produce singulated interconnect substrates.

A core layer made of glass may sometimes be used in an interconnect substrate. In this case, there is a possibility that the side surface of the core layer made of glass has structural defects, such as chips or cracks, after the cutting for singulation.

### Related-Art Document

### Patent Document

[Patent Document 1] Japanese Laid-Open Patent Publication No. 2018-110150

### SUMMARY

According to an aspect of the embodiment, an interconnect substrate includes a core layer made of glass having one surface and another surface, a first laminate including one or more interconnect layers and one or more insulating layers and disposed on the one surface of the core layer, and a resin portion, wherein a first peripheral portion of the one surface of the core layer is not covered with the first laminate, and wherein the resin portion covers a side surface of the core layer, the first peripheral portion, and a side surface of the first laminate.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating an example of an interconnect substrate according to a first embodiment;

FIG. 2 is a drawing illustrating an example of a manufacturing process of the interconnect substrate according to the first embodiment;

FIGS. 3A through 3D are drawings illustrating the example of the manufacturing process of the interconnect substrate according to the first embodiment;

FIGS. 4A through 4C are drawings illustrating the example of the manufacturing process of the interconnect substrate according to the first embodiment;

FIGS. 5A through 5C are drawings illustrating the example of the manufacturing process of the interconnect substrate according to the first embodiment;

FIG. 6 is a cross-sectional view illustrating an example of an interconnect substrate according to a first variation of the first embodiment;

FIGS. 7A through 7C are drawings illustrating an example of a manufacturing process of the interconnect substrate according to the first variation of the first embodiment;

FIG. 8 is a cross-sectional view illustrating an example of an interconnect substrate according to the second variation of the first embodiment;

FIG. 9 is a cross-sectional view illustrating an example of an interconnect substrate according to the third variation of the first embodiment;

FIGS. 10A and 10B are drawings illustrating an example of a manufacturing process of the interconnect substrate according to the third variation of the first embodiment;

FIG. 11 is a drawing illustrating the example of the manufacturing process of the interconnect substrate according to the third variation of the first embodiment; and

FIG. 12 is a cross-sectional view illustrating an example of a semiconductor device according to the second embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### First Embodiment

### Structure of Interconnect Substrate

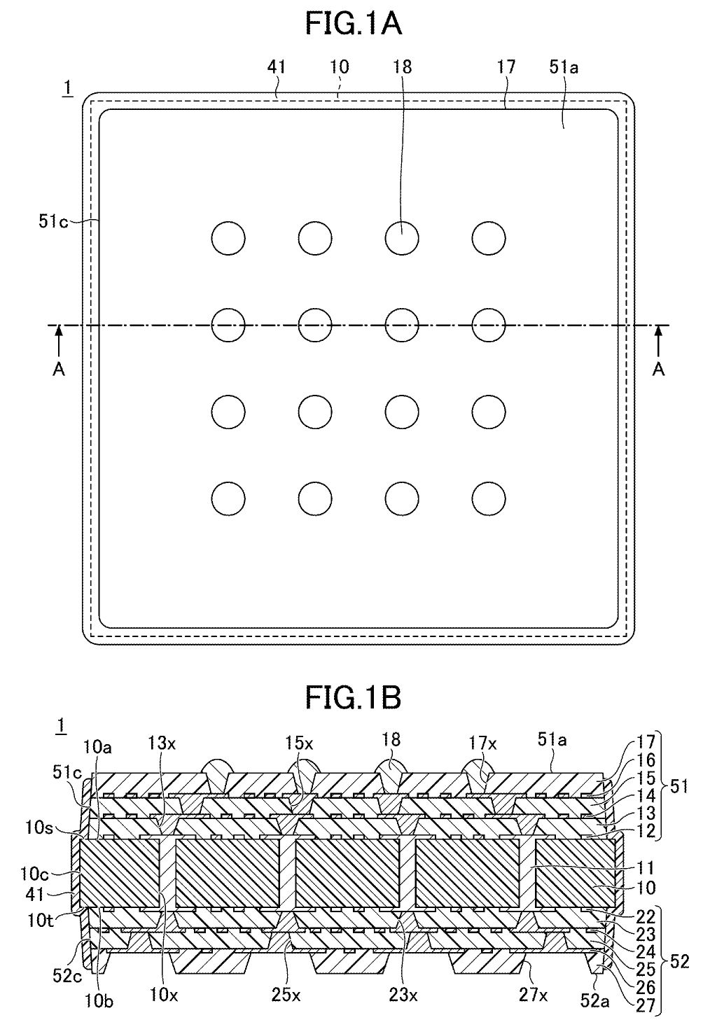

FIGS. 1A and 1B are drawings illustrating an example of an interconnect substrate according to a first embodiment. FIG. 1A is a plan view and FIG. 1B is a cross-sectional view taken along the line A-A in FIG. 1A.

Referring to FIGS. 1A and 1B, an interconnect substrate 1 includes a core layer 10 having a first surface 10a and a second surface 10b opposite the first surface 10a, a first laminate 51 including interconnect layers and insulating layers alternately laminated on the first surface 10a of the core layer 10, a second laminate 52 including interconnect layers and insulating layers alternately laminated on the second surface 10b of the core layer 10, and a resin portion 41. The interconnect substrate 1 may include external connection terminals 18. The interconnect substrate 1 may be formed to have a rectangular shape in plan view, for example.

The first laminate 51 includes an interconnect layer 12, an insulating layer 13, an interconnect layer 14, an insulating layer 15, an interconnect layer 16, and a solder resist layer 17 sequentially laminated on the first surface 10a of the core layer 10. The second laminate 52 includes an interconnect layer 22, an insulating layer 23, an interconnect layer 24, an insulating layer 25, an interconnect layer 26, and a solder resist layer 27 sequentially laminated on the second surface 10b of the core layer 10. The first laminate 51 may be formed to have a rectangular shape in plan view, for example. Each corner of the first laminate 51 may be formed as a curved shape, for example. The second laminate 52 may be formed to have a rectangular shape in plan view, for example. Each corner of the second laminate 52 may be formed as a curved surface, for example.

In the first embodiment, for convenience, the solder resist layer 17 side of the interconnect substrate 1 is referred to as an upper side or a first side, and the solder resist layer 27 side is referred to as a lower side or a second side. The surface of a portion oriented in the same direction as the solder resist layer 17 side is referred to as a first surface or an upper surface, and the surface of the portion oriented in the same direction as the solder resist layer 27 side is referred to as a second surface or a lower surface. However, the interconnect substrate 1 may be positioned upside down when used, or may be arranged at any angle. The plan view refers to the view of an object as seen from the direction normal to the first surface 10a of the core layer 10, and the plan shape refers to the shape of an object as seen from the direction normal to the first surface 10a of the core layer 10.

The core layer 10 may be formed to have a rectangular shape in plan view, for example. The core layer 10 is made of glass. Although the kind of glass constituting the core layer 10 is not limited, alkali-free glass, quartz glass, borosilicate glass, or the like may be used, for example. The thickness of the core layer 10 is, for example, in the range of approximately 100 to 1000 μm. The core layer 10 has through holes 10x that extend through the core layer 10 in the thickness direction. The plan shape of each of the through holes 10x is, for example, circular. The diameter of each of the through holes 10x may be, for example, from 100 μm to 500 μm.

A first peripheral portion 10s of the first surface 10a of the core layer 10 is not covered with the first laminate 51. The first peripheral portion 10s is, for example, coplanar with the portion of the first surface 10a of the core layer 10 on which the first laminate 51 is formed. The first peripheral portion 10s is positioned on the outer side of the first laminate 51 in plan view and has a closed-loop shape. The width of the first peripheral portion 10s may be, for example, from 50 μm to 300 μm.

A side surface 51c of the first laminate 51 is constituted by the side surface of the insulating layer 13, the side surface of the insulating layer 15, and the side surface of the solder resist layer 17. The side surface 51cof the first laminate 51 is inclined inward toward the solder resist layer 17, in the direction away from the side surface 10c of the core layer 10, in cross-sectional view, for example. Alternatively, the side surface 51c of the first laminate 51 may be perpendicular to the first surface 10a of the core layer 10.

A second peripheral portion 10t of the second surface 10b of the core layer 10 is not covered with the second laminate 52. The second peripheral portion 10t is, for example, coplanar with the portion of the second surface 10b of the core layer 10 on which the second laminate 52 is formed. The second peripheral portion 10t is positioned on the outer side of the second laminate 52 in plan view and has a closed-loop shape. The width of the second peripheral portion 10t may be, for example, from 50 μm to 300 μm.

A side surface 52c of the second laminate 52 is constituted by the side surface of the insulating layer 23, the side surface of the insulating layer 25, and the side surface of the solder resist layer 27. The side surface 52c of the second laminate 52 is inclined inward toward the solder resist layer 27, in the direction away from the side surface 10c of the core layer 10, in cross-sectional view, for example. Alternatively, the side surface 52c of the second laminate 52 may be perpendicular to the second surface 10b of the core layer 10.

The resin portion 41 covers the side surface 10c of the core layer 10, the first peripheral portion 10s, at least a portion of the side surface 51c of the first laminate 51 close to the first peripheral portion 10s, the second peripheral portion 10t, and at least a portion of the side surface 52c of the second laminate 52 close to the second peripheral portion 10t. The resin portion 41 continuously and seamlessly covers the side surfaces from the side surface 51c of the first laminate 51 to the side surface 52c of the second laminate 52. The resin portion 41 does not reach either the first surface 51a of the first laminate 51 or the second surface 52a of the second laminate 52. That is, neither the first surface 51a of the first laminate 51 nor the second surface 52a of the second laminate 52 has the resin portion 41 formed thereon . The first surface 51a is the surface of the first laminate 51 on the side facing away from the core layer 10, which is the upper surface of the first laminate 51 in the example illustrated in FIGS. 1A and 1B. The second surface 52a is the surface of the second laminate 52 on the side facing away from the core layer 10, which is the lower surface of the second laminate 52 in the example illustrated in FIGS. 1A and 1B.

The resin portion 41 may reach the side surface of the solder resist layer 17 which is the outermost insulating layer of the first laminate 51. The resin portion 41 may cover the entire side surface of the solder resist layer 17, as long as it does not extend to the first surface 51a of the first laminate 51. The resin portion 41 may reach the side surface of the solder resist layer 27 which is the outermost insulating layer of the second laminate 52. The resin portion 41 may cover the entire side surface of the solder resist layer 27, as long as it does not extend to the second surface 52a of the second laminate 52.

The resin portion 41 is disposed in a closed-loop shape on the outer side of the side surface 10c of the core layer 10 in plan view. In the resin portion 41 covering the side surface 10c of the core layer 10, the distance from the side surface 10c to the side surface of the resin portion 41 is constant, for example, throughout the thickness of the core layer 10. The distance from the side surface 10c of the core layer 10 to the side surface of the resin portion 41 is, for example, from 10 μm to 200 μm. The material of the resin portion 41 may be, for example, a photosensitive insulating resin mainly composed of an epoxy-based resin or a polyimide-based resin. Alternatively, the material of the resin portion 41 may be a thermosetting non-photosensitive insulating resin mainly composed of an epoxy-based resin or a polyimide-based resin.

The interconnect layer 12 is disposed on the first surface 10a of the core layer 10. The interconnect layer 22 is disposed on the second surface 10b of the core layer 10. The interconnect layer 12 and the interconnect layer 22 are electrically connected via through interconnects 11 formed in the through holes 10x. Each of the interconnect layers 12 and 22 is patterned in a predetermined plan shape. The interconnect layers 12 and 22 and the through interconnects 11 may be made of, for example, copper (Cu). The thicknesses of the interconnect layers 12 and 22 are, for example, in the range of approximately 10 to 40 μm. The interconnect layer 12, the interconnect layer 22, and the through interconnects 11 may be seamlessly formed.

The insulating layer 13 is an interlayer insulating layer disposed on the first surface 10a of the core layer 10 and covering the interconnect layer 12. The material of the insulating layer 13 may be, for example, an insulating resin or the like mainly composed of an epoxy-based resin or a polyimide-based resin. The thickness of the insulating layer 13 may be, for example, in the range of approximately 30 to 40 μm. The insulating layer 13 may contain a filler such as silica (SiO₂).

Via holes 13x are formed in the insulating layer 13 to extend through the insulating layer 13 and reach the upper surface of the interconnect layer 12. The via holes 13x may each be an inverted truncated conical hole for which the diameter of the opening toward the insulating layer 15 is larger than the diameter of the opening at the upper surface of the interconnect layer 12.

The interconnect layer 14 is formed on the first side of the insulating layer 13. The interconnect layer 14 includes via interconnects filling the via holes 13x and an interconnect pattern formed on the upper surface of the insulating layer 13. The interconnect pattern is electrically connected to the interconnect layer 12 via the via interconnects. The material of the interconnect layer 14 and the thickness of the interconnect pattern may be substantially the same as those of the interconnect layer 12, for example.

The insulating layer 15 is formed on the upper surface of the insulating layer 13 so as to cover the interconnect layer 14. The material and the thickness of the insulating layer 15 may be substantially the same as those of the insulating layer 13, for example. The insulating layer 15 may contain a filler such as silica (SiO₂).

Via holes 15x are formed in the insulating layer 15 to extend through the insulating layer 15 and reach the upper surface of the interconnect layer 14. The via holes 15x may each be an inverted truncated conical hole for which the diameter of the opening toward the solder resist layer 17 is larger than the diameter of the opening at the upper surface of the interconnect layer 14.

The interconnect layer 16 is formed on the first side of the insulating layer 15. The interconnect layer 16 includes via interconnects filling the via holes 15x and pads formed on the upper surface of the insulating layer 15. The pads are electrically connected to the interconnect layer 14 through the via interconnects. The material of the interconnect layer 16 and the thickness of the pads may be substantially the same as those of the interconnect layer 12, for example. The thickness of the pads may be larger than that of the interconnect layer 12. The interconnect layer 16 may also include an interconnect pattern in addition to the pads.

The solder resist layer 17 is an outermost insulating layer of the first laminate 51, and is formed on the upper surface of the insulating layer 15 so as to cover the interconnect layer 16. The solder resist layer 17 may be formed of, for example, a photosensitive epoxy-based insulating resin or acrylic-based insulating resin. The thickness of the solder resist layer 17 is, for example, in the range of approximately 15 to 35 μm.

The solder resist layer 17 has openings 17x, and portions of the upper surface of the interconnect layer 16 are located within the openings 17x. The plan shape of each of the openings 17x may be, for example, circular. The interconnect layer 16 situated in the openings 17x may be used as pads for electrical connections with a semiconductor chip, for example. That is, the first surface 51a of the first laminate 51 of the interconnect substrate 1 is a chip mounting surface on which a semiconductor chip is to be mounted.

On the surface of the interconnect layer 16 exposed in the openings 17x, a metal layer may be formed, or an organic coating may be formed by applying an antioxidant treatment such as organic solderability preservative (OSP) treatment. Examples of the metal layer include an Au layer, a Ni/Au layer (a metal layer formed by laminating a Ni layer and an Au layer in this order), a Ni/Pd/Au layer (a metal layer formed by laminating a Ni layer, a Pd layer, and an Au layer in this order), and a Sn layer.

According to need, the external connection terminals 18 may be provided on the interconnect layer 16 exposed in the openings 17x. The external connection terminals 18 are, for example, solder bumps. The material of the solder bumps may be, for example, an alloy containing Pb, an alloy of Sn and Cu, an alloy of Sn and Ag, an alloy of Sn, Ag and Cu, or the like.

The insulating layer 23 is an interlayer insulating layer disposed on the second surface 10b of the core layer 10 and covering the interconnect layer 22. The material and the thickness of the insulating layer 23 may be substantially the same as those of the insulating layer 13, for example. The insulating layer 23 may contain a filler such as silica (SiO₂).

Via holes 23x are formed in the insulating layer 23 to extend through the insulating layer 23 and reach the lower surface of the interconnect layer 22. The via holes 23x may each be a truncated conical hole for which the diameter of the opening toward the insulating layer 25 is larger than the diameter of the opening at the lower surface of the interconnect layer 22.

The interconnect layer 24 is formed on the second side of the insulating layer 23. The interconnect layer 24 includes via interconnects filling the via holes 23x and an interconnect pattern formed on the lower surface of the insulating layer 23. The interconnect pattern is electrically connected to the interconnect layer 22 via the via interconnects. The material and thickness of the interconnect layer 24 may be substantially the same as those of the interconnect layer 12, for example.

The insulating layer 25 is formed so as to cover the interconnect layer 24 on the lower surface of the insulating layer 23. The material and thickness of the insulating layer 25 may be substantially the same as those of the insulating layer 13, for example. The insulating layer 25 may contain a filler such as silica (SiO₂).

Via holes 25x are formed in the insulating layer 25 to extend through the insulating layer 25 and reach the lower surface of the interconnect layer 24. The via holes 25x may each be a truncated conical hole for which the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 via the via interconnects. The material and the thickness of the interconnect layer 26 may be substantially the same as those of the interconnect layer 12, for example.

The solder resist layer 27 is an outermost insulating layer of the second laminate 52, and is formed on the lower surface of the insulating layer 25 so as to cover the interconnect layer 26. The material and thickness of the solder resist layer 27 may be substantially the same as those of the solder resist layer 17, for example. The solder resist layer 27 has openings 27x, and portions of the lower surface of the interconnect layer 26 are exposed within the openings 27x. The plan shape of each of the openings 27x may be, for example, circular. The interconnect layer 26 exposed in the openings 27x may be used as pads for electrical connections to a mounting substrate such as a motherboard. If necessary, a metal layer of the kind previously described may be formed on the lower surface of the interconnect layer 26 exposed in the openings 27x, or an oxidation prevention treatment such as OSP treatment may be applied.

As described heretofore, the side surface 10c of the core layer 10 of the interconnect substrate 1 is covered with the resin portion 41. This arrangement effectively reduces the breakage, such as chipping or cracking, of the side surface 10c of the core layer 10.

In addition to the side surface 10c of the core layer 10, the resin portion 41 covers the first peripheral portion 10s, at least of a portion of the side surface 51c of the first laminate 51 close to the first peripheral portion 10s , the second peripheral portion 10t, and at least a portion of the side surface 52c of the second laminate 52 close to the second peripheral portion 10t. This arrangement effectively increases the rigidity of the interconnect substrate 1.

From the viewpoint of increasing the rigidity of the interconnect substrate 1, it is preferable for the resin portion 41 to cover the side surface 51c as completely as possible without reaching the first surface 51a. For example, the resin portion 41 preferably reaches the side surface of the solder resist layer 17 which is the outermost insulating layer of the first laminate 51. Similarly, from the viewpoint of increasing the rigidity of the interconnect substrate 1, it is preferable for the resin portion 41 to cover the side surface 52c as completely as possible without reaching the second surface 52a. For example, the resin portion 41 preferably extends to the side surface of the solder resist layer 27 which is the outermost insulating layer of the second laminate 52.

Further, the interconnect substrate 1 may be placed on a flat surface with the first surface 51a facing downward to measure the warpage of the interconnect substrate 1 in certain cases. The interconnect substrate 1 is such that the resin portion 41 does not reach the first surface 51a. That is, unnecessary irregularities caused by the outflow of the resin portion 41 are not formed on the first surface 51a. This arrangement thus allows the accurate measurement of the warpage of the interconnect substrate 1.

Further, the interconnect substrate 1 may be placed on a flat surface with the second surface 52a facing downward to measure the warpage of the interconnect substrate 1 in certain cases. The interconnect substrate 1 is such that the resin portion 41 does not reach the second surface 52a. That is, unnecessary irregularities caused by the outflow of the resin portion 41 are not formed on the second surface 52a. This arrangement thus allows the accurate measurement of the warpage of the interconnect substrate 1.

Further, to optimize the appearance of the interconnect substrate 1, preferably, the resin portion 41 should not reach the first surface 51a and the resin portion 41 should not reach the second surface 52a .

### Method of Making Interconnect Substrate

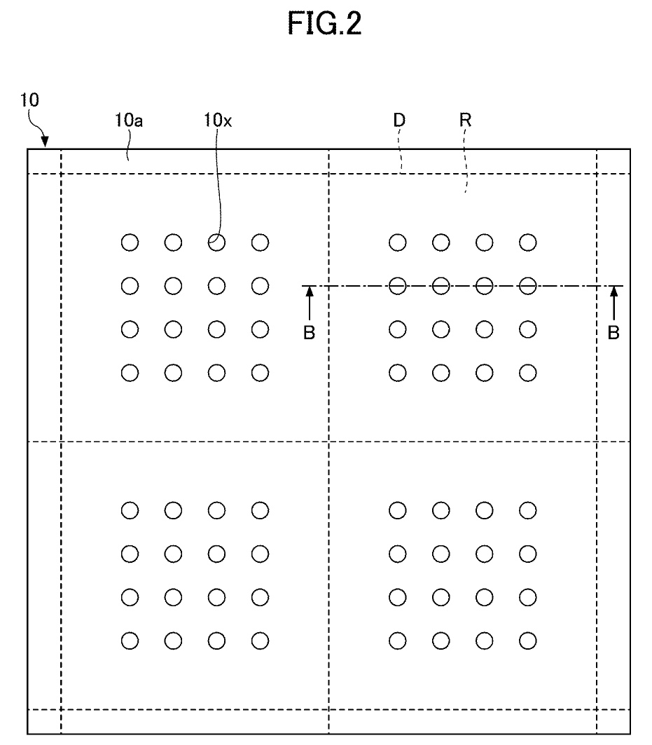

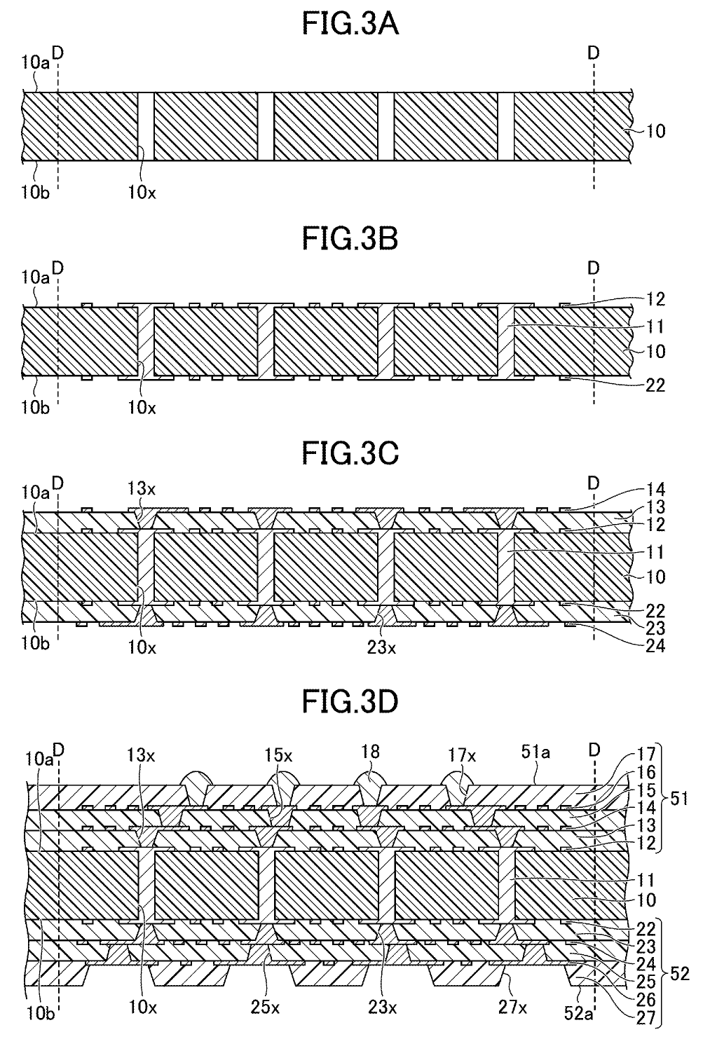

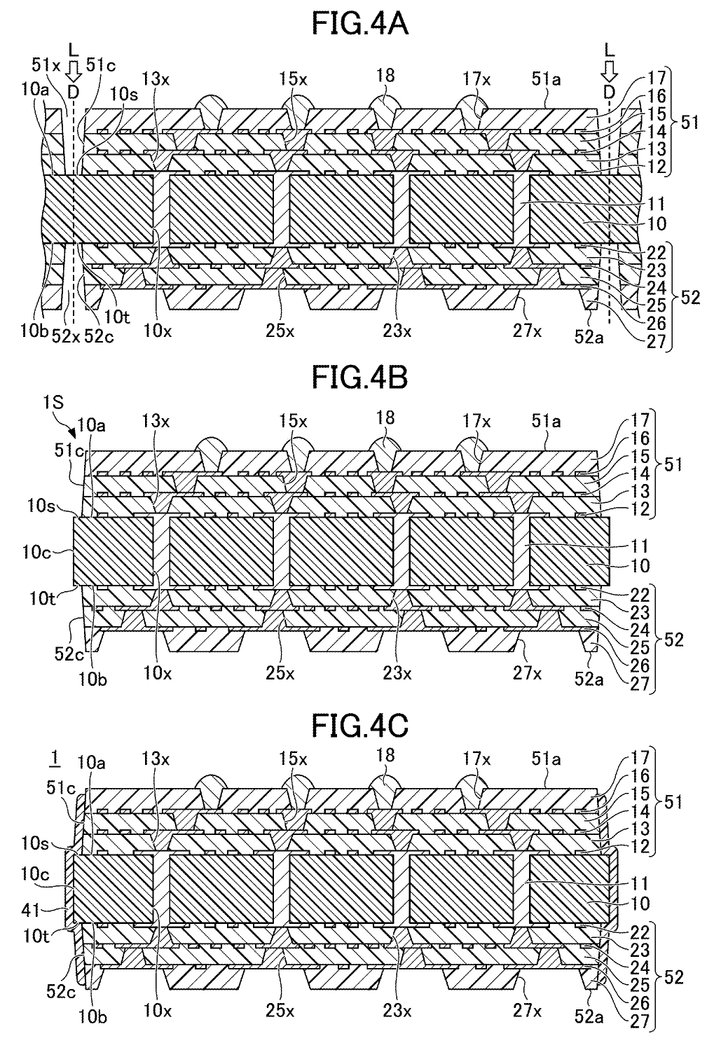

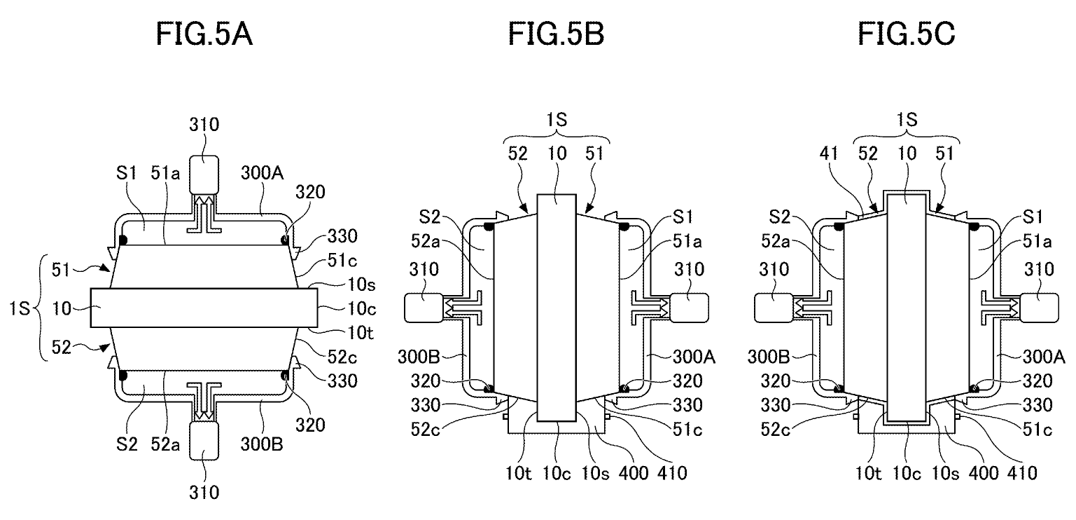

FIG. 2 through FIGS. 5A to 5C are drawings illustrating an example of a manufacturing process of the interconnect substrate according to the first embodiment. FIG. 2 is a plan view, and FIGS. 3A to 3D and FIGS. 4A to 4C are partial cross-sectional views corresponding to the position of the line B-B in FIG. 2. FIGS. 5A through 5C are schematic drawings illustrating an example of a preferred method of forming the resin portion.

First, in the step illustrated in FIGS. 2 and 3A, a core layer 10 made of glass is prepared. The core layer 10 includes a plurality of interconnect regions R for singulation into interconnect substrates, and cutting regions D along which cuts are to be made for singulation. Although the cutting regions D are illustrated by lines in FIGS. 2 and 3A, they may each be a region having a constant width. Next, through holes 10x extending from the first surface 10a to the second surface 10b are formed in the core layer 10 inside each interconnect region R.

The through holes 10x may be formed by wet etching, for example. Examples of the etching solution used in this process include hydrofluoric acid, strong alkali solution, and the like. If the through holes 10x were formed by drilling, there would be a risk of cracking in the glass of the core layer 10. However, the use of wet etching enables the formation of the through holes 10x without causing cracks in the glass.

In the steps illustrated in FIGS. 3B to 3D, a first laminate 51 including alternately laminated interconnect layers and insulating layers is formed on the first surface 10a of the core layer 10. Further, a second laminate 52 including alternately laminated interconnect layers and insulating layers is formed on the second surface 10b of the core layer 10. Specifically, as illustrated in FIG. 3B, an interconnect layer 12 is formed in each interconnect region R on the first surface 10a of the core layer 10, and an interconnect layer 22 is formed in each interconnect region R on the second surface of the core layer 10, with through interconnects 11 formed in the through holes 10x. For example, a seed layer (copper or the like) covering the first surface 10a and the second surface 10b of the core layer 10 and the inner wall surfaces of the through holes 10x is formed by an electroless plating method, a sputtering method, or the like, and an electroplating layer (copper or the like) is formed on the seed layer by an electroplating method using the seed layer as a current supply path. This arrangement fills the through holes 10x with the electrolytic plating layer formed on the seed layer, and forms a conductive layer as a laminate of the seed layer and the electrolytic plating layer on each of the first surface 10a and the second surface 10b of the core layer 10. Thereafter, the conductor layers are patterned into predetermined plan shapes by a subtractive method or the like to form the interconnect layers 12 and 22 and the through interconnects 11.

As illustrated in FIG. 3C, insulating layers 13 and 23 and interconnect layers 14 and 24 are formed. First, the insulating layer 13 covering the upper surface of the interconnect layer 12 is disposed in each interconnect region R and each cutting region D on the first surface 10a of the core layer 10. Specifically, for example, a semi-cured epoxy-based resin film or the like is laminated on the first surface 10a of the core layer 10 so as to cover the interconnect layer 12, and then cured to form the insulating layer 13. Alternatively, instead of laminating epoxy-based resin film or the like, epoxy-based resin or the like in liquid or paste form may be applied and then cured to form the insulating layer 13. The material and the thickness of the insulating layer 13 are as previously described. Similarly, the insulating layer 23 covering the lower surface of the interconnect layer 22 is disposed in each interconnect region R and each cutting region D on the second surface 10b of the core layer 10.

Next, via holes 13x are formed in the insulating layer 13 to penetrate the insulating layer 13 and expose the upper surface of the interconnect layer 12. Further, via holes 23x are formed in the insulating layer 23 to penetrate the insulating layer 23 and expose the lower surface of the interconnect layer 22. The via holes 13x and 23x may be formed by, for example, laser processing using a CO₂ laser or the like. After the via holes 13x and 23x are formed, desmearing is preferably performed to remove resin residues adhering to the surfaces of the interconnect layers 12 and 22 exposed at the end of the via holes 13x and 23x.

The interconnect layer 14 is then formed on the first side of the insulating layer 13. The interconnect layer 14 includes via interconnects filling the via holes 13x and an interconnect pattern formed on the upper surface of the insulating layer 13. The interconnect layer 14 is electrically connected to the interconnect layer 12 exposed at the bottom of the via holes 13x. Similarly, the interconnect layer 24 is formed on the second side of the insulating layer 23. The interconnect layer 24 includes via interconnects filling the via holes 23x and an interconnect pattern formed on the lower surface of the insulating layer 23. The interconnect layer 24 is electrically connected to the interconnect layer 22 exposed at the end of the via holes 23x. The materials of the interconnect layers 14 and 24 and the thicknesses of the interconnect patterns may be substantially the same as those of the interconnect layer 12, for example. The interconnect layers 14 and 24 are formed, for example, by a semi-additive method.

As illustrated in FIG. 3D, insulating layers 15 and 25, interconnect layers 16 and 26, solder resist layers 17 and 27, and external connection terminals 18 are formed. First, the same steps as those of FIG. 3C are repeated to form the insulating layers 15 and 25 and the interconnect layers 16 and 26. Next, the solder resist layer 17 is formed on the upper surface of the insulating layer 15 so as to cover the interconnect layer 16. Further, the solder resist layer 27 is formed on the lower surface of the insulating layer 25 so as to cover the interconnect layer 26. The solder resist layer 17 may be formed, for example, by applying a photosensitive epoxy-based insulating resin in liquid or paste form to the upper surface of the insulating layer 15 so as to cover the interconnect layer 16 by screen printing, roll coating, spin coating, or the like. Alternatively, a photosensitive epoxy-based insulating resin film, for example, may be laminated on the upper surface of the insulating layer 15 so as to cover the interconnect layer 16. The method for forming the solder resist layer 27 is substantially the same as that for forming the solder resist layer 17. Thereafter, the solder resist layers 17 and 27 are exposed and developed. As a result, openings 17x are formed to expose the interconnect layer 16 through the solder resist layer 17. Also, openings 27x for exposing portions of the lower surface of the interconnect layer 26 are formed in the solder resist layer 27. According to need, the external connection terminals 18 may be provided on the interconnect layer 16 exposed in the openings 17x. The external connection terminals 18 are, for example, solder bumps formed by solder reflow or the like.

In the step illustrated in FIG. 4A, first grooves 51x, each straddling a corresponding cutting region D, are formed so as to penetrate the first laminate 51 and expose the first surface 10a of the core layer 10. The first grooves 51x are formed along the cutting regions D and throughout the cutting regions D. In each interconnect region R, the first surface 10a of the core layer 10 exposed in the first grooves 51x is a portion that becomes the first peripheral portion 10s after singulation. Further, second grooves 52x, each straddling a corresponding cutting region D, are formed so as to penetrate the second laminate 52 and expose the second surface 10b of the core layer 10. The second grooves 52x are formed along the cutting regions D and throughout the cutting regions D. In each interconnect region R, the second surface 10b of the core layer 10 exposed in the second grooves 52x is a portion that becomes the second peripheral portion 10t after singulation. The first grooves 51x and the second grooves 52x may be formed, for example, by irradiating the first laminate 51 and the second laminate 52 with a laser beam having an absorptive wavelength. In the case of irradiation with the laser beam, the widths of the first grooves 51x and the second grooves 52x increase with the distance from the core layer 10, for example. By adjusting the irradiation area of the laser beam for forming the first grooves 51x and the second grooves 52x, the corners of the first laminate 51 and the second laminate 52 is effectively formed into a curved shape. Forming the corners of the first laminate 51 and the second laminate 52 in curved shapes effectively prevents the cracking of the insulating layers at these corners. The first grooves 51x and the second grooves 52x may alternatively be formed by using a cutting blade.

After the first grooves 51x and the second grooves 52x are formed, the first surface 10a of the core layer 10 exposed in the first grooves 51x is irradiated with a laser beam L along the cutting regions D. By condensing the laser beam inside the core layer 10, a modified layer serving as a starting point for division is formed inside the core layer 10 at the positions located under the cutting regions D. In this step, the core layer 10 is irradiated with a laser beam having a transmissive wavelength.

In the step illustrated in FIG. 4B, the core layer 10 is cut along the cutting regions D illustrated in FIG. 4A to produce a plurality of singulated structures 1S. By cutting along the cutting regions D, the first grooves 51x are each divided, and in each structure 1S, the first surface 10a of the core layer 10 that was originally exposed in the first grooves 51x becomes the first peripheral portion 10s. Further, the second grooves 52x are each divided, and in each structure 1S, the second surface 10b of the core layer 10 that was originally exposed in the second grooves 52x becomes the second peripheral portion 10t.

The cutting may be performed, for example, by attaching the structure illustrated in FIG. 4A to an expansion tape and stretching the tape radially outward with respect to the structure. Stretching the tape causes forces to be applied to the modified portions of the core layer 10 in the radially outward direction in which the tape expands. As a result, the core layer 10 is divided along the modified layer serving as the starting point of separation.

Instead of the method of using the expansion tape, for example, a roller or a rod-shaped pressing member may be used to apply a force around the cutting regions D to divide the core layer 10.

In the step illustrated in FIG. 4C, a resin portion 41 is formed on each of the singulated structures 1S illustrated in FIG. 4B The resin portion 41 is formed so as to cover the side surface 10c of the core layer 10, the first peripheral portion 10s, at least a portion of the side surface 51c of the first laminate 51 close to the first peripheral portion 10s, the second peripheral portion 10t, and at least a portion of the side surface 52c of the second laminate 52 close to the second peripheral portion 10t. The resin portion 41 does not reach either the first surface 51a of the first laminate 51 or the second surface 52a of the second laminate 52. That is, neither the first surface 51a of the first laminate 51 nor the second surface 52a of the second laminate 52 has the resin portion 41 formed thereon . Through this process, the manufacture of the interconnect substrate 1 is completed. Although the resin portion 41 may be formed by any method in the step of forming the resin portion 41, an example of a preferred forming method will be described with reference to FIGS. 5A through 5C.

First, as illustrated in FIG. 5A, a chamber 300A is prepared, and a portion of the side surface 51c of the first laminate 51 located close to the first surface 51a is held by the inner wall surface of the distal end of the chamber 300 A. This arrangement effectively forms a sealed space S1 between the inner wall surface of the chamber 300A and the first surface 51a of the first laminate 51. The sealed space S1 may be evacuated and depressurized by the depressurizing device 310. This enables the chamber 300A to stably hold the first laminate 51. In FIGS. 5A to 5C, arrows indicate the direction in which air is withdrawn by the depressurizing device 310.

The chamber 300A preferably has a sealing material 320 of a closed-loop shape in plan view that is in contact with the inner wall surface. The sealing material 320 may have a sufficient flexibility to achieve a sealing function. Examples of the flexible material include silicone rubber and soft urethane.

When the distal end of the chamber 300A holds the first laminate 51, the sealing material 320 is positioned to contact the full perimeter of the first surface 51a of the first laminate 51 in plan view. Preferably, the outer wall surface of the distal end of the chamber 300A has a protrusion 330 projecting away from the side surface 51c in a closed-loop shape in plan view. Providing the protrusion 330 restricts resin flow to the outside in the direction perpendicular to the first surface 51a during a subsequent process of applying a liquid resin.

Similarly, a chamber 300B is prepared, and a portion of the side surface 52c of the second laminate 52 close to the second surface 52a is held by the inner wall surface of the distal end of the chamber 300B, thereby forming a sealed space S2 with the second surface 52a. The sealed space S2 may be evacuated and depressurized by the depressurizing device 310. This enables the chamber 300B to stably hold the second laminate 52.

The chamber 300B preferably has a sealing material 320 of a closed-loop shape in plan view that is in contact with the inner wall surface. When the distal end of the chamber 300B holds the second laminate 52, the sealing material 320 is positioned to contact the full perimeter of the second surface 52a of the second laminate 52 in plan view. Preferably, the outer wall surface of the distal end of the chamber 300B has a protrusion 330 projecting away from the side surface 52c in a closed-loop shape in plan view. Providing the protrusion 330 restricts resin flow to the outside in the direction perpendicular to the second surface 52a during a subsequent process of applying a liquid resin.

As illustrated in FIG. 5B, with the first surface 51a of the first laminate 51 and the second surface 52a of the second laminate 52 arranged parallel to the vertical direction, the structure 1S is placed on a roller 400 impregnated with liquid resin. The roller 400 is rotatable around the rotation axis 410. Here, the vertical direction refers to the direction of gravity. As an example, a sponge or porous roller 400 made of a resin such as urethane may be used as the roller 400. The roller 400 may be a tubular cylinder or a solid cylinder.

As illustrated in FIG. 5C, resin liquid is applied to the side surface 10c of the core layer 10, the first peripheral portion 10s, at least a portion of the side surface 51c of the first laminate 51 close to the first peripheral portion 10s, the second peripheral portion 10t, and at least a portion of the side surface 52c of the second laminate 52 close to the second peripheral portion 10t.

For example, while the roller 400 is rotated around the rotation axis 410, the structure 1S is rotated around a horizontal axis so that the side surface 10c and the like of the core layer 10 exposed outside the chambers 300A and 300B of the structure 1S are continuously brought into contact with the roller 400. Since the roller 400 made of sponge or the like has flexibility and elasticity, the roller surface enables effective resin application. This arrangement effectively applies the resin liquid to the side surface 10c of the core layer 10 and the like exposed outside the chambers 300A and 300B of the structure 1S. Thereafter, the liquid resin is cured by exposure or heating to form the resin portion 41.

The resin portion 41 is formed on the side surface 10c, the first peripheral portion 10s, and the second peripheral portion 10t of the core layer 10. The resin portion 41 is also formed on the side surfaces 51c and 52c except for the portion of the side surface 51c of the first laminate 51 close to the first surface 51a which is in contact with the distal end of the chamber 300A and the portion of the side surface 52c of the second laminate 52 close to the second surface 52a which is in contact with the distal end of the chamber 300B.

As described above, during the step of forming the resin portion 41, the periphery of the first surface 51a of the first laminate 51 and the periphery of the second surface 52a of the second laminate 52 are sealed, so that the resin liquid is effectively prevented from flowing to the first surface 51a and the second surface 52a. This arrangement successfully forms the resin portion 41 which covers at least a portion of the side surface 51c of the first laminate 51 close to the first peripheral portion 10s and at least a portion of the side surface 52c of the second laminate 52 close to the second peripheral portion 10t without extending to the first surface 51a and the second surface 52a.

In addition, the first peripheral portion 10s of the first surface 10a of the core layer 10 is exposed outside the first laminate 51, and the second peripheral portion 10t of the second surface 10b of the core layer 10 is exposed outside the second laminate 52. As a result, the roller 400 contacts the side surface 10c of the core layer 10 but does not fully contact either the side surface 51c of the first laminate 51 or the side surface 52c of the second laminate 52. This arrangement prevents an excessive amount of the resin liquid from being attached to the side surface 51c of the first laminate 51 and the side surface 52c of the second laminate 52, thereby effectively avoiding the flow of the resin liquid to the outside in the directions perpendicular to the first surface 51a and the second surface 52a.

### Variations of First Embodiment

Variations of the first embodiment are directed to examples of interconnect substrates having shapes different from that of the first embodiment. In connection with the variations of the first embodiment, descriptions of the same components as those of the already described embodiment may be omitted.

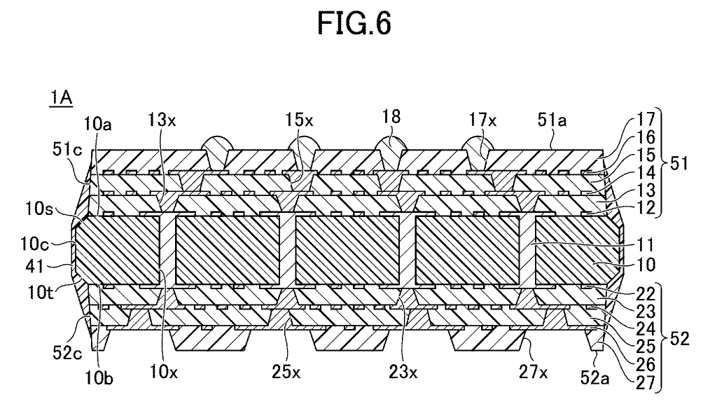

FIG. 6 is a cross-sectional view illustrating an example of an interconnect substrate according to a first variation of the first embodiment; An interconnect substrate 1A illustrated in FIG. 6 differs from the interconnect substrate 1 in that the first peripheral portion 10s of the first surface 10a of the core layer 10 is inclined with respect to the portion of the first surface 10a of the core layer 10 on which the first laminate 51 is formed. Further, the interconnect substrate 1A illustrated in FIG. 6 differs from the interconnect substrate 1 in that the second peripheral portion 10t of the second surface 10b of the core layer 10 is inclined with respect to the portion of the second surface 10b of the core layer 10 on which the second laminate 52 is formed.

The first peripheral portion 10s is inclined such that its end toward the side surface 10c of the core layer 10 is closer to the second surface 10b of the core layer 10 in the thickness direction than its end toward the first laminate 51. The second peripheral portion 10t is inclined such that its end toward the side surface 10c of the core layer 10 is closer to the first surface 10a of the core layer 10 in the thickness direction than its end toward the second laminate 52.

The first peripheral portion 10s and the second peripheral portion 10t are each linear in cross-sectional view, for example. The first peripheral portion 10s and the second peripheral portion 10t may each be curved in cross-sectional view, or may each include one or more straight portions and one or more curved portions.

When the first peripheral portion 10s is linear in cross-sectional view, an angle formed by the extension of the portion of the first surface 10a bearing the first laminate 51 and the first peripheral portion 10s is, for example, from 30 degrees to 60 degrees. The first peripheral portion 10s is located outside the imaginary extension of the side surface 51c projecting toward the second surface 10b in cross-sectional view.

When the second peripheral portion 10t is linear in cross-sectional view, an angle formed by the extension of the portion of the second surface 10b bearing the second laminate 52 and the second peripheral portion 10t is, for example, from 30 degrees to 60 degrees. The second peripheral portion 10t is located outside the imaginary extension of the side surface 52c projecting toward the first surface 10a in cross-sectional view.

Here, the direction parallel to the portion of the first surface 10a on which the first laminate 51 is formed is referred to as the first direction. Then, the thickness in the first direction of the resin portion 41 covering the first peripheral portion 10s is greater than or equal to the thickness of the resin portion 41 covering the side surface 10c in the first direction. The thickness in the first direction of the resin portion 41 covering the first peripheral portion 10s gradually increases, for example, away from the side surface 10c toward the first laminate 51. The thickness in the first direction of the resin portion 41 covering the side surface 51c of the first laminate 51 gradually decreases, for example, away from the first peripheral portion 10s toward the solder resist layer 17.

The thickness in the first direction of the resin portion 41 covering the second peripheral portion 10t is greater than or equal to the thickness in the first direction of the resin portion 41 covering the side surface 10c. The thickness in the first direction of the resin portion 41 covering the second peripheral portion 10t gradually increases, for example, away from the side surface 10c toward the second laminate 52. The thickness in the first direction of the resin portion 41 covering the side surface 52c of the second laminate 52 gradually decreases, for example, away from the second peripheral portion 10t toward the solder resist layer 27.

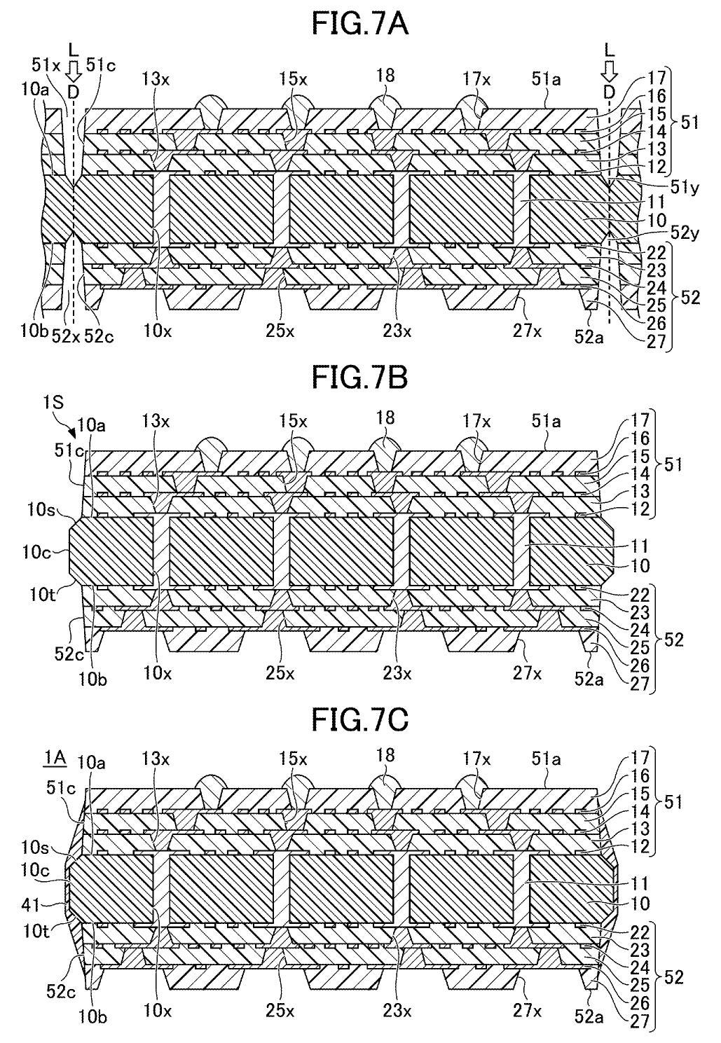

FIGS. 7A through 7C are drawings illustrating an example of a manufacturing process of the interconnect substrate according to the first variation of the first embodiment; To manufacture the interconnect substrate 1A, recesses 51y continuous with the first grooves 51x are formed in the core layer 10 exposed in the first grooves 51x between the step of forming the first grooves 51x and the step of cutting the core layer 10 along the cutting regions D. Further, recesses 52y continuous with the second grooves 52x are formed in the core layer 10 exposed in the second grooves 52x between the step of forming the second grooves 52x and the step of cutting the core layer 10 along the cutting regions D.

Specifically, first, a process substantially similar to that of FIGS. 2 to 4A is carried out to form a modified layer serving as a starting point of division in the core layer 10 located below the cutting regions D. Then, as illustrated in FIG. 7A, the first surface 10a of the core layer 10 exposed in the first grooves 51x is irradiated with a laser beam L again along the cutting regions D, thereby forming recesses 51y continuous with the first grooves 51x in the core layer 10. Further, the second surface 10b of the core layer 10 exposed in the second grooves 52x is irradiated with a laser beam L again along the cutting regions D, thereby forming recesses 52y continuous with the second grooves 52x in the core layer 10. The recesses 51y and 52y may each be formed, for example, in a V-shape in cross-sectional view. Alternatively, the recesses 51y and 52y may each have a shape close to a U-shape in cross-sectional view. Alternatively, the recesses 51y and 52y may be formed by machining using a blade or the like.

Next, as illustrated in FIG. 7B, the core layer 10 is cut along the cutting regions D depicted in FIG. 7A to produce a plurality of singulated structures 1S. By cutting along the cutting regions D, the first grooves 51x and the recesses 51y are each divided, and in each structure 1S, the recesses 51y originally exposed in the first grooves 51x become the first peripheral portion 10s inclined with respect to the portion of the first surface 10a bearing the first laminate 51. Further, the second grooves 52x and the recesses 52y are each divided, and in each structure 1S, the recesses 52y originally exposed in the second grooves 52x become the second peripheral portion 10t inclined with respect to the portion of the second surface 10b bearing the second laminate 52. The cutting may be performed, for example, by a method substantially similar to that illustrated in FIG. 4B.

As illustrated in FIG. 7C, the resin portion 41 is formed on the singulated structure 1S illustrated in FIG. 7B, thereby completing the interconnect substrate 1A illustrated in FIG. 6. The resin portion 41 may be formed, for example, by substantially the same method as that described with reference to FIG. 5.

As described above, the interconnect substrate 1A is configured such that the thickness of the resin portion 41 covering the first peripheral portion 10s and the second peripheral portion 10t is effectively increased. The corners of the core layer 10 in cross-sectional view are prone to breakage such as chipping or cracking. By increasing the thickness of the resin portion 41 covering the first peripheral portion 10s and the second peripheral portion 10t located at the corners of the core layer 10 in cross-sectional view, breakage such as chipping or cracking is less likely to occur, thereby effectively improving the reliability of the interconnect substrate 1A.

In addition, the surface roughness of the first peripheral portion 10s and the second peripheral portion 10t formed by laser irradiation is greater than that of the side surface 10c of the core layer 10 divided along the modified layer portion. This arrangement effectively improves the adhesion between the resin portion 41 and each of the first peripheral portion 10s and the second peripheral portion 10t. The first peripheral portion 10s and the second peripheral portion 10t formed by machining using a blade or the like also have a surface roughness larger than that of the side surface 10c of the core layer 10 divided along the modified layer portion, thereby effectively achieving substantially the same advantageous result as described above.

It may not be desirable to adopt the configuration in which the core layer 10 has no vertical side surface with the first peripheral portion 10s and the second peripheral portion 10t intersecting each other. This is because panel layout optimization at the time of fabricating the interconnect substrate 1A becomes difficult, which leads to an increase in the cost of the interconnect substrate 1A.

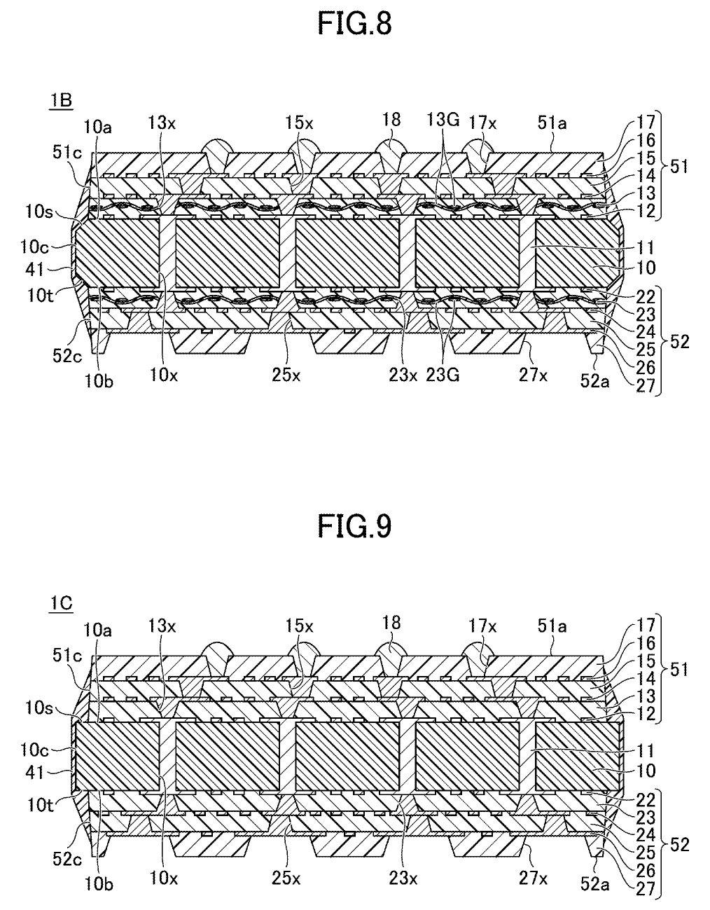

FIG. 8 is a cross-sectional view illustrating an example of an interconnect substrate according to the second variation of the first embodiment; An interconnect substrate 1B illustrated in FIG. 8 differs from the interconnect substrate 1A in that the insulating layer 13 includes a reinforcing member 13G and the insulating layer 23 includes a reinforcing member 23G. Examples of the reinforcing members 13G and 23G include glass cloth formed of glass fiber bundles. Instead of the glass fiber bundles, carbon fiber bundles, polyester fiber bundles, a nylon (polyamide) fiber bundles, aramid fiber bundles, or the like may be used. The reinforcing members 13G and 23G may be woven fabrics or nonwoven fabrics.

An end of the reinforcing member 13G may be exposed or protruded from the side surface 51c of the first laminate 51 in some cases. An end of the reinforcing member 23G may be exposed or protruded from the side surface 52c of the second laminate 52 in some cases. In these cases, the resin constituting the resin portion 41 permeates into the end portion of the reinforcing member 13G and the end portion of the reinforcing member 23G, which effectively improves the adhesion between the resin portion 41 and each of the first laminate 51 and the second laminate 52.

It may be noted that the reinforcing member may be provided in any of the insulating layers. The reinforcing member may be provided only in the insulating layer next to the outermost solder resist layer, or may be provided in all of the insulating layers.

FIG. 9 is a cross-sectional view illustrating an example of an interconnect substrate according to the third variation of the first embodiment; The interconnect substrate 1C illustrated in FIG. 9 is configured such that the thickness of the resin portion 41 covering the side surface 10c of the core layer 10 is thinner than that of the interconnect substrate 1. In the interconnect substrate 1C, the shape of the resin portion 41 is approximately the same as that of the interconnect substrate 1A illustrated in FIG. 6.

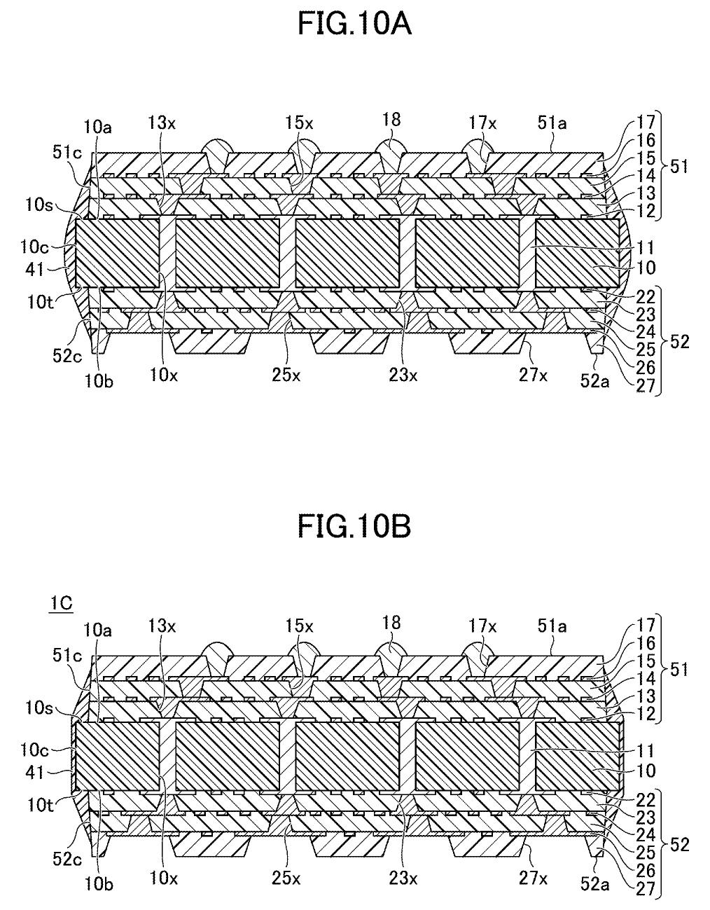

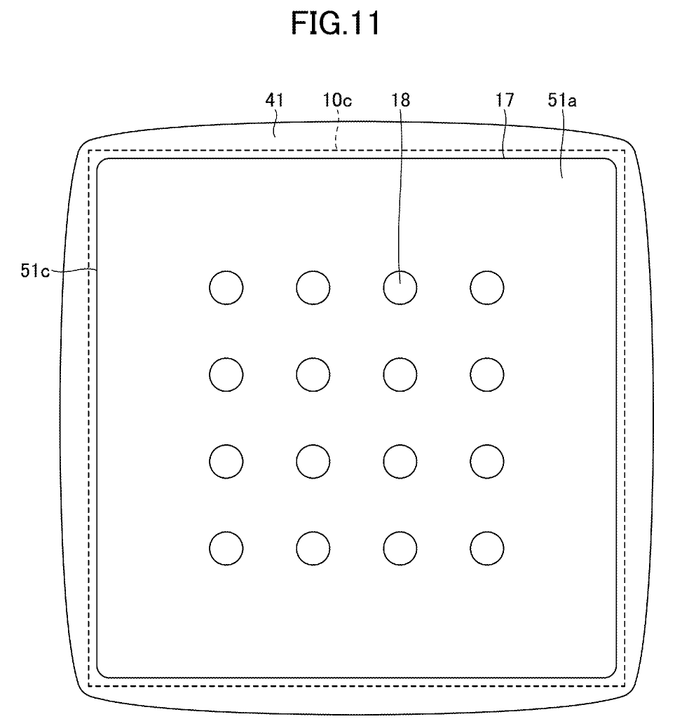

FIGS. 10A and 10B and FIG. 11 are drawings illustrating a manufacturing process of the interconnect substrate according to the third variation of the first embodiment. To manufacture the interconnect substrate 1C, the resin portion 41 covering the side surface 10c of the core layer 10 is thinned after the step of forming the resin portion 41.

Specifically, first, the same steps as those in FIG. 2 to FIGS. 5A through 5C are performed to form the resin portion 41. At this time, by applying a relatively large amount of resin for the resin portion 41, the resin portion 41 covering the side surface 10c becomes thick as illustrated in FIG. 10A.

As illustrated in FIG. 10B, the portion of the resin portion 41 covering the side surface 10c is thinned to complete the interconnect substrate 1C. The thinning may be carried out, for example, using a trimming device. Alternatively, the excess amount of the resin portion 41 may be removed using a plate having a shape similar to a ruler before curing , followed by curing the resin portion 41.

In the step illustrated in FIG. 10A, in some cases, the thickness of the resin portion 41 covering the side surface 10c may be reduced in the vicinity of the corners of the core layer 10 and increased between the adjacent corners as depicted in plan view in FIG. 11. Although the excess amount of the resin portion 41 may be removed along the entire perimeter of the resin portion 41 in plan view, the structure as illustrated in FIG. 11 may be treated by reducing the resin portion 41 only along perimeter portions excluding the corners in plan view.

The interconnect substrate 1C is configured as described above, so that reducing the thickness of the periphery of the resin portion 41 in plan view facilitates reducing variations in the outer dimensions of the interconnect substrate 1C. In addition, the size of the interconnect substrate 1C is effectively reduced in the lateral directions.

### Second Embodiment

The second embodiment is directed to an example of a semiconductor device in which a semiconductor chip is mounted on the interconnect substrate according to the first embodiment. In connection with the second embodiment, descriptions of the same components as those of the already described embodiment may be omitted.

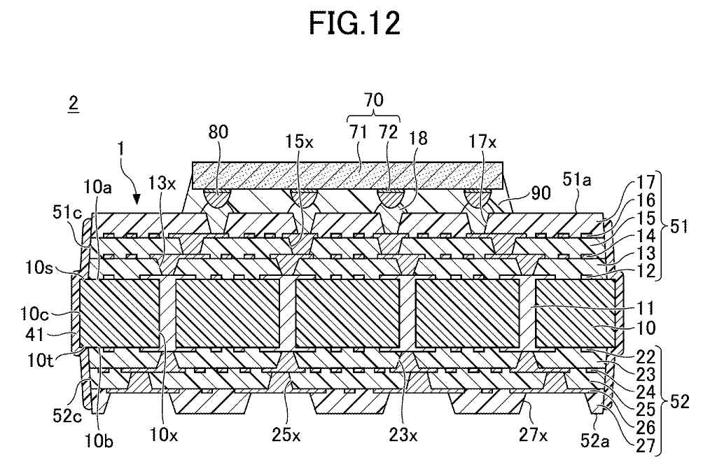

FIG. 12 is a cross-sectional view illustrating an example of a semiconductor device according to the second embodiment. Referring to FIG. 12, a semiconductor device 2 includes the interconnect substrate 1 illustrated in FIG. 1, a semiconductor chip 70, bumps 80, and an underfill resin 90.

The semiconductor chip 70 includes a chip 71 and electrodes 72. The chip 71 is configured such that a semiconductor integrated circuit (not illustrated) or the like is formed on a thin semiconductor substrate (not illustrated) made of, for example, silicon. The electrodes 72 electrically connected to the semiconductor integrated circuit are formed on the semiconductor substrate (not illustrated).

The bumps 80 are formed on the electrodes 72 of the semiconductor chip 70, and electrically connects the electrodes 72 and the external connection terminals 18 of the interconnect substrate 1. The electrodes 72 may be formed of, for example, copper. The bumps 80 are, for example, solder bumps. The material of the solder bumps may be, for example, an alloy containing Pb, an alloy of Sn and Cu, an alloy of Sn and Ag, an alloy of Sn, Ag and Cu, or the like. The underfill resin 90 fills a gap between the semiconductor chip 70 and the upper surface of the solder resist layer 17 of the interconnect substrate 1. The underfill resin 90 may be formed, for example, by pouring a liquid resin from one or more ends of the first surface 51a into the gap between the semiconductor chip 70 and the upper surface of the solder resist layer 17 of the interconnect substrate 1, followed by curing the liquid resin.

In this manner, the fabrication of a semiconductor device is effectively achieved by mounting the semiconductor chip on the interconnect substrate according to the first embodiment.

In the interconnect substrate 1, the resin portion 41 does not reach the first surface 51a, which is the chip mounting surface on which the semiconductor chip is mounted. That is, unnecessary irregularities caused by the outflow of the resin portion 41 are not formed on the first surface 51a. This arrangement effectively prevents resin flow from being obstructed during the process of pouring the liquid resin from one or more ends of the first surface 51a to form the underfill resin 90. As a result, the fabrication of the underfill resin 90 having a desired shape is enabled.

Although the preferred embodiments have been described in detail, the present invention is not limited to these embodiments, and various modifications and substitutions may be made to the above-described embodiments without departing from the scope of the appended claims.

For example, the above-described embodiments are directed to the interconnect substrate that has the first laminate on the first surface of the core layer made of glass and the second laminate on the second surface. However, the present invention may be applied to an interconnect substrate having the first laminate on the first surface of the core layer made of glass and not having the second laminate on the second surface, while providing substantially the same advantageous effects. In the case where the interconnect substrate does not have the second laminate, the through holes may not be provided in the core layer.

According to at least one embodiment, an interconnect substrate having a core layer made of glass is provided in which the breakage of the side surface of the core layer is reduced.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The disclosures herein non-exhaustively include the subject matter set forth in the following clauses.

Clause 1. A method of making an interconnect substrate, comprising:

providing a glass core layer having a plurality of interconnect regions for singulation into interconnect substrates and cutting regions along which cuts are to be made for the singulation;

forming a first laminate including one or more interconnect layers and one or more insulating layers on one surface of the core layer;

forming first grooves penetrating the first laminate and exposing the one surface of the core layer, each of the first grooves straddling a corresponding one of the cutting regions;

cutting the core layer along the cutting regions to produce a plurality of singulated structures; and

forming a resin portion after the cutting,

wherein in the cutting of the core layer, each of the singulated structures is such that a first peripheral portion of the one surface of the core layer is not covered with the first laminate, and

wherein in the forming of the resin portion, the resin portion is formed so as to cover a side surface of the core layer, the first peripheral portion, and a side surface of the first laminate.

Clause 2. The method of making an interconnect substrate according to clause 1, wherein the forming of the resin portion includes: providing a chamber; causing a portion of the side surface of the first laminate to be held by an inner wall surface of a distal end portion of the chamber, the portion being located close to a first surface of the first laminate located on a side facing away from the core layer;

applying a liquid resin to the side surface of the core layer, the first peripheral portion, and the side surface of the first laminate; and curing the liquid resin to form the resin portion.

Clause 3. The method of making an interconnect substrate according to clause 2, wherein the chamber includes a sealing material of a closed-loop shape in plan view that is in contact with the inner wall surface, and

wherein when the distal end portion of the chamber holds the first laminate, the sealing material is placed in contact with an entire periphery of the first surface of the first laminate in plan view.

Clause 4. The method of making an interconnect substrate according to clause 3, wherein the forming of the resin portion includes applying the liquid resin with a roller.

Clause 5. The method of making an interconnect substrate according to clause 1, further comprising forming recesses each continuous with a corresponding one of the first grooves in the core layer exposed in the first grooves between the forming of the first grooves and the cutting of the core layer along the cutting regions.

Clause 6. The method of making an interconnect substrate according to clause 1, further comprising thinning a portion of the resin portion covering the side surface of the core layer after the forming of the resin portion.

Clause 7. The method of making an interconnect substrate according to clause 1, further comprising:

prior to the cutting of the core layer,

forming a second laminate including one or more interconnect layers and one or more insulating layers on another surface of the core layer; and

forming second grooves penetrating the second laminate and exposing the another surface of the core layer, each of the second grooves straddling a corresponding one of the cutting regions,

wherein in the cutting of the core layer, each of the singulated structures is such that a second peripheral portion of the another surface of the core layer is not covered with the second laminate, and

wherein in the forming of the resin portion, the resin portion is formed so as to further cover the second peripheral portion and a side surface of the second laminate.

Clause 8. The method of making an interconnect substrate according to clause 7, further comprising forming recesses each continuous with a corresponding one of the second grooves in the core layer exposed in the second grooves between the forming of the second grooves and the cutting of the core layer along the cutting regions.

What is claimed is:

1. An interconnect substrate comprising:
a core layer made of glass having one surface and another surface;
a first laminate including one or more interconnect layers and one or more insulating layers and disposed on the one surface of the core layer; and
a resin portion,
wherein a first peripheral portion of the one surface of the core layer is not covered with the first laminate, and
wherein the resin portion covers a side surface of the core layer, the first peripheral portion, and a side surface of the first laminate.

2. The interconnect substrate according to claim 1, wherein the resin portion reaches a side surface of an outermost one of the one or more insulating layers of the first laminate, and refrains from covering a first surface of the first laminate located on a side facing away from the core layer.

3. The interconnect substrate according to claim 2, wherein the first surface is a chip mounting surface on which a semiconductor chip is to be mounted.

4. The interconnect substrate according to claim 1, wherein the first peripheral portion is inclined such that an end thereof toward the side surface of the core layer is closer to the another surface of the core layer in a thickness direction than an end thereof toward the first laminate.

5. The interconnect substrate according to claim 1, wherein the first laminate includes an insulating layer provided with a reinforcing member, and an end of the reinforcing member is exposed or protruded from the side surface of the first laminate.

6. The interconnect substrate according to claim 1, further comprising a second laminate including one or more interconnect layers and one or more insulating layers and disposed on the another surface of the core layer,
wherein a second peripheral portion of the another surface of the core layer is not covered with the second laminate, and
wherein the resin portion further covers the second peripheral portion and a side surface of the second laminate.

7. The interconnect substrate according to claim 6, wherein the resin portion reaches a side surface of an outermost one of the one or more insulating layers of the second laminate, and refrains from covering a second surface of the second laminate located on a side facing away from the core layer.

8. The interconnect substrate according to claim 6, wherein the second peripheral portion is inclined such that an end thereof toward the side surface of the core layer is closer to the one surface of the core layer in a thickness direction than an end thereof toward the second laminate.

9. The interconnect substrate according to claim 6, wherein the second laminate includes an insulating layer provided with a reinforcing member, and an end of the reinforcing member is exposed or protruded from the side surface of the second laminate.
